(19) United States
(12) Patent Application Publication
(10) Pub. No.: US 2011/0164842 A1
(43) Pub. Date: Jul. 7, 2011

(54) WEAR AND CORROSION RESISTANT LAYERED COMPOSITE

(75) Inventors: Tim Matthias Hosenfeldt, Nuernberg (DE); Bertram Haag, Uhlfeld (DE); Yashar Musayev, Nuernberg (DE)

(73) Assignee: SCHAEFFLER TECHNOLOGIES GMBH & CO. KG, Herzogenaurach (DE)

(21) Appl. No.: 13/061,816

(22) PCT Filed: Aug. 26, 2009
(86) PCT No.: PCT/EP2009/061010

§ 371 Date: Mar. 2, 2011

(30) Foreign Application Priority Data
Sep. 2, 2008 (DE) 10 2008 045 381.1

(51) Int. Cl. F16C 33/00; B32B 15/04; C23C 28/00; C23C 16/50; C23C 16/32

(52) U.S. Cl. 384/625; 428/457; 205/191; 205/183; 427/569; 427/577; 427/249.18; 427/248.1

(57) ABSTRACT

A layered composite which has a substrate made of a ferrous material with a PVD/PACVD coating and a corrosion protection layer that is disposed on the PVD/PACVD coating. The PVD/PACVD coating has pores into which the corrosion protection layer protrudes.

The present invention relates to a wear- and corrosion-inhibiting layer composite and a process for producing such a layer composite.

Coatings are used to protect components subject to tribological and corrosion stress against wear. This wear, particularly in the case of material pairings which move against one another in a state which is not hydrodynamically lubricated, frequently occurs as a result of various wear mechanisms which occur individually or in combination. For these reasons, the structuring of moving components by means of wear- and corrosion-protection layers so as to optimally match the stress is gaining increasing importance.

There are individual processes by means of which tribological properties can be improved in a targeted manner, but without offering appropriate corrosion protection. The corrosion protection layers which are available according to the prior art do not have satisfactory tribological properties such as minimization of friction and wear resistance. Layer systems which can be applied by means of PVD (physical vapor deposition) or PACVD (plasma-aided chemical vapor deposition) are known, but while these have good tribological properties they have only unsatisfactory corrosion resistance. Electrochemically, chemically or autocatalytically applied protective layers are known for corrosion protection, but these have only a low tribological resistance.

DE 10 2006 049 756 A1 discloses a wear protection layer which is made up of a plurality of layers of different hard material-containing and metallic phases. A particular corrosion protection layer is not provided in this layer system.

DE 2417920A discloses a process for producing a chromium carbide layer on the surface of an article made of iron, an iron alloy or cemented hard material. In this process, a melt bath comprising a chromium halide and boric acid and/or borate is used.

DE 10 242 421 A1 discloses a coating based on niobium nitride or niobium metal nitride for protecting a substrate against wear and corrosion, with intermediate layers being applied to improve the adhesion. Niobium nitride is a hard material layer having a very great hardness. Furthermore, niobium nitride is extremely resistant to corrosive attack. The niobium nitride layer therefore fulfils both the task of corrosion protection and the function of a tribologically resistant coating. However, coating with a niobium nitride layer is relatively costly.

It is therefore an object of the present invention to provide a layer system which can be applied to iron material and combines very good tribological properties with excellent corrosion protection properties and is also inexpensive to produce.

This object is achieved according to the invention in the terms of a product by a layer system having the features of claim 1 and in terms of a process by a process for applying the layer system as claimed in claim 10.

A layer composite according to the invention has a substrate composed of an iron material, which substrate has a PVD/PACVD coating and has a corrosion protection layer which is arranged on the PVD/PACVD coating, where the PVD-PACVD coating has pores into which the corrosion protection layer projects.

The concept underlying the present invention is to form a hybrid layer system which comprises a hard material layer and a corrosion protection layer which are applied to an iron material. In this way, it is possible to achieve, in a targeted manner, properties on the component surface which combine the properties of the individual applied layers.

The dependent claims provide advantageous embodiments and improvements of/to the layer system as set forth in claim 1 and of/to the process for producing such a layer system as set forth in claim 10.

The invention is illustrated below with the aid of examples and reference to the accompanying figures. In the figures:

FIG. 1 schematically shows a cross section of a layer system according to the invention as per a first preferred example; and

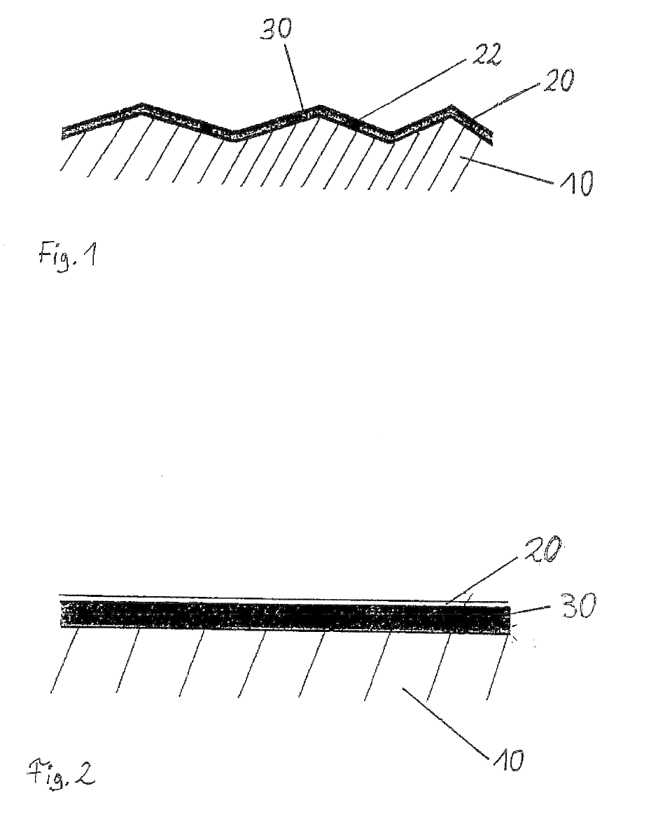

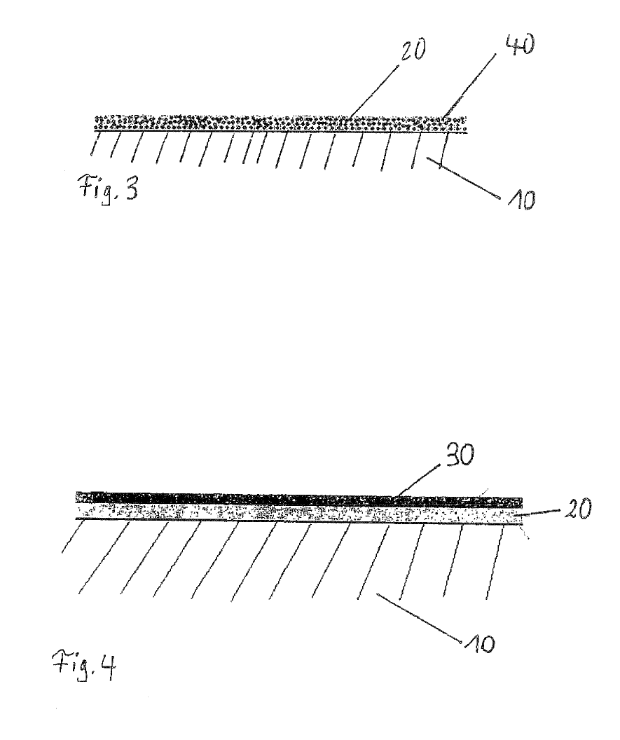

FIG. 2 schematically shows a cross section of a layer system according to the invention as per a second preferred example; and

FIG. 3 schematically shows a cross section of a layer system according to the invention as per a third preferred example; and

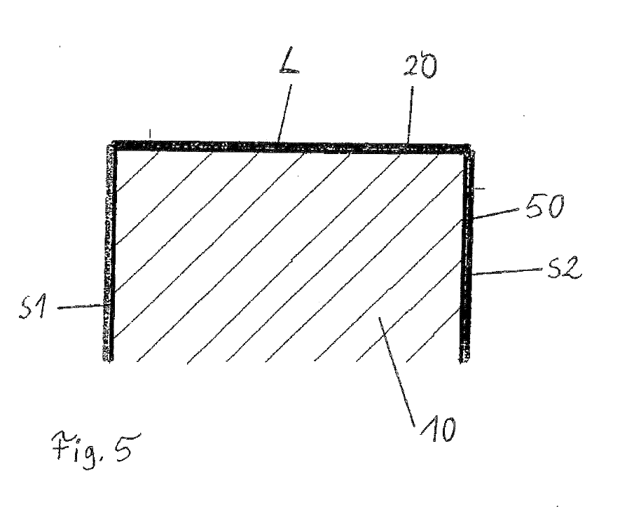

FIG. 4 schematically shows a cross section of a layer system according to the invention having a covering layer, a functional layer and a substrate; and

FIG. 5 schematically shows a cross section of a layer system according to the invention having a multilayer coating on a substrate.

In the figures, the same reference signs denote identical components or components having the same function, unless indicated otherwise.

FIG. 1 schematically shows a cross section of a layer system according to the invention as per a first preferred example. A component or substrate 10 is provided with a PVD/PACVD coating 20. The PVD/PACVD coating 20 has pores 22. The PVD/PACVD coating is sealed by a corrosion protection layer 30. The component comprises an iron material and is, for example, a bearing component on a machine or in an engine. The PVD/PACVD coating 20 has excellent tribological properties, e.g. minimization of friction and wear protection. However, this layer 20 is not completely closed due to its small layer thickness and process-related properties, i.e. the layer 20 has pores 22, known as pinholes, which prevent a corrosion-protective barrier action of the layer 20. To provide this tribologically active layer 20 with additional good corrosion protection, it is provided with an organic/inorganic/mineral sealing layer 30 which closes the pinholes 22 and in the rolled-over state is incorporated into the pores 22. According to the invention, sol-gel layers are also used for the sealing layer 30. The insulation obtained in this way ensures anodic corrosion protection.

FIG. 2 schematically shows a cross section of a layer system according to the invention as per a second preferred example of the present invention. An electrochemically, chemically or autocatalytically applied layer 20 is applied to a component 10. A PVD/PACVD layer 20 is present on the layer 30.

The electrochemically, chemically or autocatalytically applied layer 30 serves as support layer for the PVD/PACVD layer 20 and can be applied both for corrosion protection reasons and for wear reasons. Owing to the stress on, for example, bearing components, tribocorrosion and thus component failure frequently occurs. This means that abrasive stress on the component combined with corrosive stress occurs. This is prevented by the electrochemically, autocatalytically or chemically applied layer 30. In addition, this layer 20 gives economic advantages in production since a bonding layer between substrate 10 and tribological function layer 20 is generally required in the PVD/PACVD process and is normally deposited in situ, i.e. at the start of the PVD/PACVD process, by the PVD process. The previous electrochemical, chemical or autocatalytic coating enables this process step to be dispensed with and accordingly allows the process time to be shortened. In addition, the costs for the appropriate target materials for the support layer applied by the PVD process are not incurred.

FIG. 3 schematically shows a cross section of a layer system according to the invention as per a further preferred example. Here, a chromium carbide layer 40 is present on a component 10. This chromium carbide layer 40 is produced by applying a layer 20 composed of chromium or a chromium alloy to the component 10. In a subsequent process step, the layer 20 is converted into a chromium carbide layer 40 in a PVD/PACVD process, e.g. by means of an etching process step or in an in-situ PVD process. Here, the layer is restructured and densified.

FIG. 4 schematically shows a cross section of a layer system according to the invention having a covering layer, a functional layer and a substrate. A layer 20 produced by a PVD/PACVD process is present on a component 10. A covering layer 30 is present on this layer. The layer 20 has a porosity in the form of pores and pinholes and therefore does not ensure sufficient corrosion protection. To ensure sufficient corrosion protection, the component is, after production of the layer 20 by means of a PVD/PACVD process, subsequently subjected to an electrochemical, chemical or autocatalytic treatment to form the covering layer 30 which has both covalent bonding character and ionic or metallic bonding character. In this way, the pores formed in the PVD/PACVD process are closed and anodic/cathodic corrosion protection action is thus produced while maintaining the tribological properties of the PVD/PACVD layer.

FIG. 5 schematically shows a cross section of a layer system according to the invention having a multilayer coating on a substrate. A cylindrical component (e.g. a bucket tappet) 10 has a layer 20 produced by a PVD/PACVD process on its outer running surface L. An electrochemically, chemically or autocatalytically produced layer, e.g. a zinc alloy layer, has been applied on the left-hand end face S1 and the right-hand end face S2 of the component 10. This zinc alloy layer 50 offers corrosion protection. In this way, the desired properties can be produced and combined in a targeted manner on one component. In this example, the component thus has a functional tribologically stressable layer 20 on the upper side and also a corrosion protection layer 50 on the sides of the component 10. This technology makes it possible to achieve wear protection, minimization of friction and corrosion protection locally in a targeted manner on the component.

### List of Reference Signs

10 Substrate
20 PVD/PACVD coating
22 Pores
30 Corrosion protection layer
40 Chromium carbide layer
50 Zinc alloy layer
L Running surface
S1 First end face
S2 Second end face

1-10. (canceled)

11. A layer composite, comprising:
a substrate composed of an iron material;
a PVD/PACVD coating on the substrate; and
a corrosion protection layer arranged on the PVD/PACVD coating, the PVD-PACVD coating having pores into which the corrosion protection layer projects.

12. The layer composite as claimed in claim 11, wherein the corrosion protection layer forms bridges to the substrate via the pores.

13. The layer composite as claimed in claim 11, wherein the corrosion protection layer has both a covalent bonding characteristic and an ionic or metallic bonding characteristic.

14. A layer composite, comprising:
a substrate composed of an iron material;
an electrochemical, chemical or autocatalytic coating on the substrate; and
a PVD/PACVD coating arranged on the electrochemical, chemical or autocatalytic coating.

15. A bearing component, comprising:
a substrate composed of an iron material and having a running surface and side faces;
a PVD/PACVD coating on the running surface; and
an electrochemical, chemical or autocatalytic layer on the side faces.

16. The bearing component as claimed in claim 15, wherein the autocatalytic layer is an electrochemically, chemically or autocatalytically produced layer which provides both anodic and cathodic corrosion protection to steel.

17. The bearing component as claimed in claim 16, wherein the autocatalytic layer is a zinc alloy layer.

18. The bearing component as claimed in claim 16, wherein the autocatalytic layer is a nickel alloy layer.

19. A process for producing a layer composite comprising a substrate composed of an iron material, having an electrochemical, chemical or autocatalytic coating and a PVD/PACVD coating, the process comprising the following steps:
providing a substrate composed of an iron material;
applying an electrochemical, chemical or autocatalytic coating to the substrate; and
applying a PVD/PACVD coating to the electrochemical, chemical or autocatalytic coating.

20. A process for producing a layer composite comprising a substrate composed of an iron material, having a PVD/PACVD coating and a corrosion protection layer arranged on the PVD/PACVD coating, the PVD-PACVD coating having pores into which the corrosion protection layer projects, the process comprising the following steps:
providing of a substrate composed of an iron material;
applying a PVD/PACVD coating to the substrate; and
applying an electrochemical, chemical or autocatalytic coating to the PVD/PACVD coating.

21. A process for producing a layer composite, comprising the following process steps:
providing a substrate composed of an iron material;
applying a layer composed of chromium or a chromium alloy to the substrate; and
converting the layer into a chromium carbide layer by a PVD/PACVD process.
